(19) United States
(12) Patent Application Publication
(10) Pub. No.: US 2026/0239836 A1
(43) Pub. Date: Aug. 13, 2026

(54) ELECTRONIC APPARATUS

(71) Applicant: Samsung Display Co., Ltd., Yongin-si (KR)

(72) Inventors: Minkyung PARK, Yongin-si (KR); WONSE LEE, Yongin-si (KR); JI-EUN LEE, Yongin-si (KR); DONGHYEON JANG, Yongin-si (KR)

(21) Appl. No.: 19/410,402

(22) Filed: Dec. 5, 2025

(30) Foreign Application Priority Data
Feb. 10, 2025 (KR) 10-2025-0016864

(51) Int. Cl. H10K 59/131; H10K 59/121; H10K 59/80

(52) U.S. Cl. CPC H10K 59/131; H10K 59/1213; H10K 59/8722; H10K 59/873

(57) ABSTRACT

An electronic apparatus includes: a pixel in a display area; a power line configured to provide a power to the pixel; a data line configured to provide a data signal to the pixel and comprising a first data line part in the display area and a second data line part connected to the first data line part and in a non-display area; an inorganic layer covering the data line; a power pattern connected to the power line; a sealing member in the non-display area and covering at least a portion of the power pattern; an encapsulation substrate on the sealing member; and an organic layer on the inorganic layer, at least a portion of which is spaced apart from the sealing member, and a portion of the inorganic layer overlapping a separation space between the organic layer and the sealing member is covered by the power pattern.

### CROSS-REFERENCE TO RELATED APPLICATION

The present application claims priority to and the benefit of Korean Patent Application No. 10-2025-0016864, filed on Feb. 10, 2025, in the Korean Intellectual Property Office, the entire disclosure of which is incorporated herein by reference.

### BACKGROUND

### 1. Field

Aspects of some embodiments of the present disclosure relate to an electronic apparatus.

### 2. Description of Related Art

Various display panels applied to multimedia electronic apparatuses, such as televisions, mobile phones, tablet computers, navigation devices, and game devices, are being developed. Display panels generally include a display area displaying images and a peripheral area that is a non-display area surrounding the display area. Pixels, which are the smallest units to display images, are arranged in the display area. Each pixel includes a pixel circuit and a light emitting element connected to the pixel circuit. Fan-out lines are arranged in the peripheral area to apply signals and voltages to the pixels.

In recent years, as a bezel area of electronic apparatuses has reduced, an effective area where fan-out lines are arranged is gradually decreasing. As a result, the density of fan-out lines has generally increased, which may lead to a decline in reliability, for example, the likelihood of corrosion occurring on the surface of the fan-out lines may increase, and cracks may occur in an inorganic insulating layer formed on the fan-out lines.

The above information disclosed in this Background section is only for enhancement of understanding of the background and therefore the information discussed in this Background section does not necessarily constitute prior art.

### SUMMARY

Aspects of some embodiments of the present disclosure relate to an electronic apparatus. For example, aspects of some embodiments of the present disclosure relate to an electronic apparatus with a narrow bezel.

Aspects of some embodiments of the present disclosure include an electronic apparatus with a relatively narrow bezel and relatively improved reliability.

Aspects of some embodiments of the present disclosure include an electronic apparatus including a base layer including a display area and a non-display area, a pixel in the display area, a power line providing a power to the pixel, a data line providing a data signal to the pixel and including a first data line part in the display area and a second data line part connected to the first data line part and in the non-display area, an inorganic layer covering the data line, a power pattern connected to the power line, on the inorganic layer, and overlapping the second data line part, a sealing member in the non-display area along a periphery of the display area and covering at least a portion of the power pattern, an encapsulation substrate on the sealing member, and an organic layer on the inorganic layer. According to some embodiments, at least a portion of the organic layer is spaced apart from the sealing member in a plan view, and a portion of the inorganic layer, which overlaps a separation space between the organic layer and the sealing member, is covered by the power pattern.

According to some embodiments, the pixel includes a transistor including a gate electrode, a source electrode, a drain electrode, and a semiconductor pattern and a light emitting element including an anode, a cathode, and a light emitting layer, and the data line is at a same layer as the gate electrode.

According to some embodiments, the source electrode or the drain electrode is at a same layer as the power pattern.

According to some embodiments, the organic layer is at a same layer as an insulating layer between the anode and the source electrode.

According to some embodiments, the first data line part and the second data line part are at a same layer.

According to some embodiments, the power line is on the first data line part, and the power pattern is on the second data line part.

According to some embodiments, the inorganic layer includes a first inorganic layer and a second inorganic layer on the first inorganic layer, and the data line includes a first line under the first inorganic layer and a second line between the first inorganic layer and the second inorganic layer.

According to some embodiments, the power pattern includes a first portion that overlaps the separation space in the plan view and has a first width in a direction and a second portion that does not overlap the separation space in the plan view and has a second width greater than the first width in the direction.

According to some embodiments, a vertical distance of the separation space in the direction is smaller than or equal to 58 micrometers in the plan view.

According to some embodiments, the second data line part includes a slant portion slanted with respect to a direction in the plan view and a linear portion extending from the slant portion along the direction, the sealing member overlaps at least a portion of the slant portion, and the organic layer overlaps at least a portion of the linear portion.

According to some embodiments, the second data line part further includes a branch portion branched from the linear portion and including a plurality of branches extending in the direction, and at least a portion of the branch portion overlaps the separation space in the plan view.

According to some embodiments, the electronic apparatus further includes a pad part connected to the data line, and the pad part is exposed without being covered by the organic layer.

Aspects of some embodiments of the present disclosure include an electronic apparatus including a base layer including a display area and a non-display area, a pixel in the display area, a power line providing a power to the pixel, a gate line extending in a first direction, a data line including a first data line part extending in a second direction intersecting the first direction and in the display area and a second data line part connected to the first data line part and in the non-display area, an inorganic layer covering the data line, a power pattern connected to the power line, on the inorganic layer, and overlapping the second data line part, a sealing member in the non-display area along a periphery of the display area and covering at least a portion of the power pattern, an encapsulation substrate on the sealing member, and an organic layer on the inorganic layer and spaced apart from the sealing member in the second direction in a plan view. According to some embodiments, at least a portion of a separation space between the organic layer and the sealing member overlaps the power pattern in the plan view.

According to some embodiments, the pixel includes a transistor including a gate electrode, a source electrode, a drain electrode, and a semiconductor pattern and a light emitting element including an anode, a cathode, and a light emitting layer, and the data line is at a same layer as the gate electrode.

According to some embodiments, the source electrode or the drain electrode is at a same layer as the power pattern.

According to some embodiments, the first data line part and the second data line part are at a same layer.

According to some embodiments, the second data line part includes a slant portion slanted with respect to the first and second directions in the plan view and a linear portion extending from the slant portion along the second direction, the sealing member overlaps at least a portion of the slant portion, and the organic layer overlaps at least a portion of the linear portion.

According to some embodiments, the second data line part further includes a branch portion branched from the linear portion and including a plurality of branches extending in the second direction, and at least a portion of the branch portion overlaps the separation space in the plan view.

According to some embodiments, at least a portion of the organic layer overlaps the power pattern in the plan view.

According to some embodiments, a width of the separation space in the second direction is smaller than or equal to 58 micrometers in the plan view.

When a bezel area is reduced, a pitch of the data line arranged near a pad area may become narrower. Consequently, the electrical characteristics of the electronic apparatus may be deteriorated, as an example, the data line may be disconnected.

For example, corrosion may be likely to occur near the data line arranged in the separation space between the sealing member, which is in the non-display area, and the organic layer, and cracks are forming in the inorganic layer that covers the data line.

According to some embodiments of the present disclosure, the inorganic layer in the separation space is covered by the power pattern, and thus, damage to the data lines arranged at narrow pitch by external forces may be prevented or relatively reduced. In addition, even when cracks form in the inorganic layer located in the separation space, the inorganic layer is covered by the power pattern, and thus, external moisture or the like reaching the data line beneath a position where the cracks are formed may be prevented or relatively reduced.

### BRIEF DESCRIPTION OF THE DRAWINGS

FIG. 1 is a block diagram of an electronic apparatus according to some embodiments of the present disclosure;

FIG. 2 is a schematic view of electronic apparatuses according to some embodiments of the present disclosure;

FIG. 3 is a perspective view of an electronic apparatus according to some embodiments of the present disclosure;

FIG. 4 is an exploded perspective view of an electronic apparatus according to some embodiments of the present disclosure;

FIG. 5 is a cross-sectional view of an electronic apparatus according to some embodiments of the present disclosure;

FIG. 6 is a plan view of a display module according to some embodiments of the present disclosure;

FIG. 7 is an equivalent circuit diagram of a pixel according to some embodiments of the present disclosure;

FIG. 8 is a cross-sectional view of a display panel according to some embodiments of the present disclosure;

FIG. 9 is an enlarged view of a portion of a display panel adjacent to a pad area according to some embodiments of the present disclosure; and

FIG. 10 is a cross-sectional view of a display panel taken along a line I-I′ of FIG. 9.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to accompanying drawings.

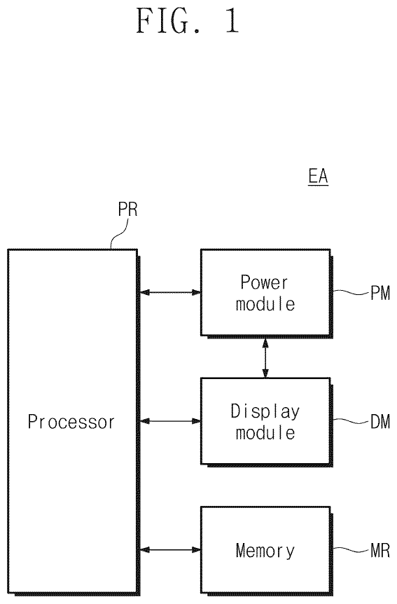

FIG. 1 is a block diagram of an electronic apparatus according to some embodiments of the present disclosure.

Referring to FIG. 1, the electronic apparatus EA may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), or a controller.

The memory MR may store data information required for the operation of the processor PR or the display module DM. When the processor PR executes an application stored in the memory MR, an image data signal and/or an input control signal may be transmitted to the display module DM, and the display module DM may process the received signals to output image information through a display screen. The display module DM may include a display panel that displays an image.

The power module PM may include a power conversion module. The power conversion module may convert power supplied by a power supply module, such as a power adapter or a battery device, to generate power required for the operation of the electronic apparatus EA.

At least one of components of the electronic apparatus EA may be included in the display module according to some embodiments as described in more detail later and a display device including the display module according to some embodiments. In addition, among individual modules that are functionally included within a single module, some may be included in the display device while others may be provided separately from the display device. As an example, the display device may include the display module DM, and the processor PR, the memory MR, and the power module PM may be provided as separate devices within the electronic apparatus EA, rather than being included in the display device.

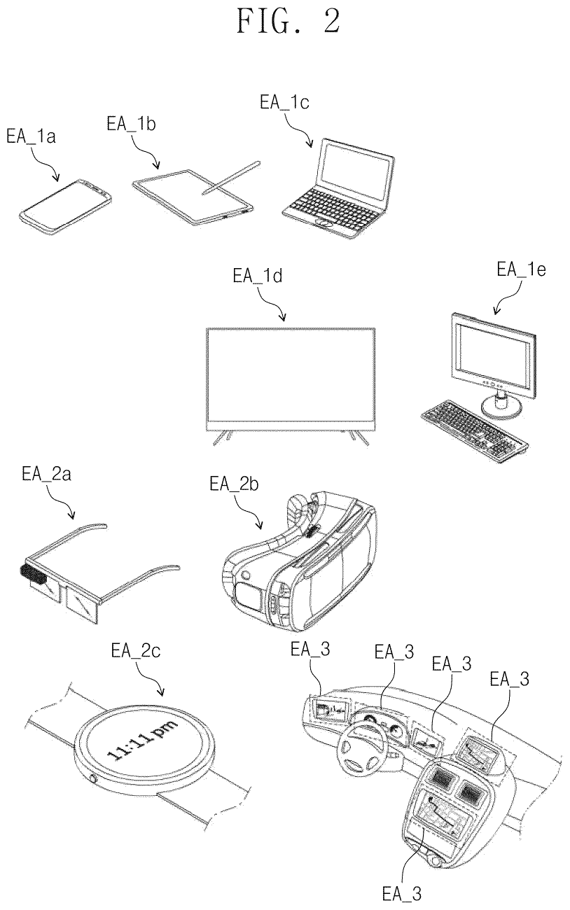

FIG. 2 is a schematic view of electronic apparatuses according to some embodiments of the present disclosure.

Referring to FIG. 2, various electronic apparatuses to which a display module according to some embodiments is applied may include an electronic apparatus for displaying images, such as a smartphone EA_1a, a tablet PC EA_1b, a laptop computer EA_1c, a television EA_1d, a desktop monitor EA_1e, etc., a wearable electronic apparatus including a display module, such as a smart glasses EA_2a, a head-mounted display EA_2b, a smartwatch EA_2c, etc., and an in-vehicle electronic apparatus EA_3 including a display module, such as an instrument panel, a center fascia, a dashboard-mounted center information display (CID), a room mirror display, etc.

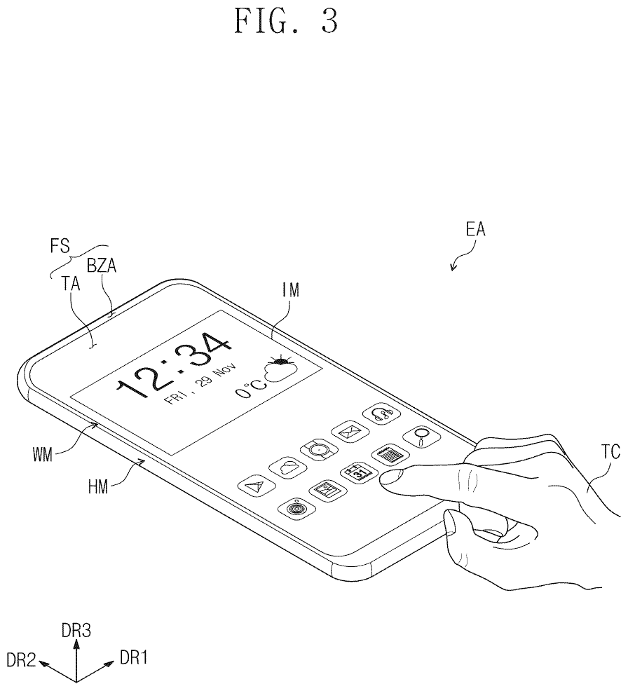

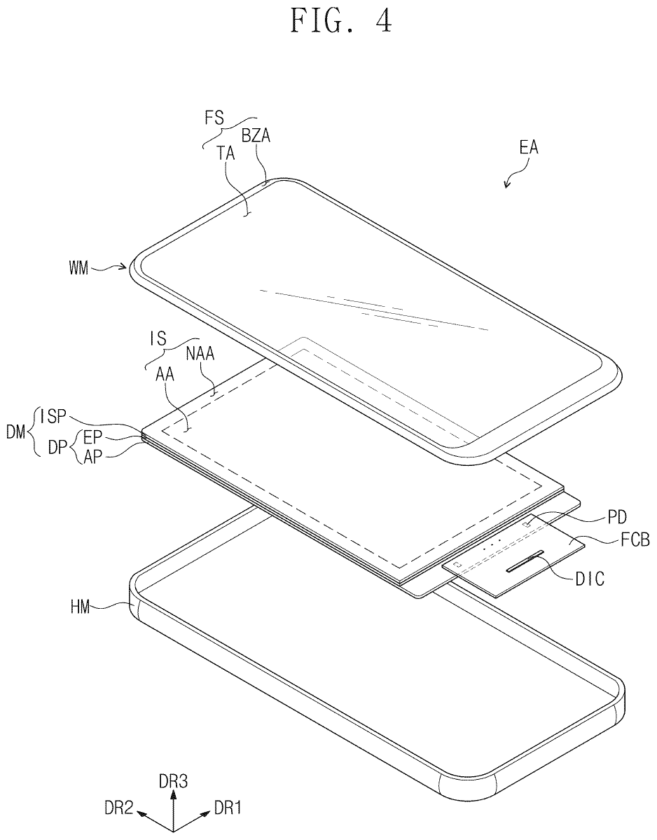

FIG. 3 is a perspective view of the electronic apparatus according to some embodiments of the present disclosure. FIG. 4 is an exploded perspective view of the electronic apparatus EA according to some embodiments of the present disclosure.

According to some embodiments, a smartphone will be described as a representative example of the electronic apparatus EA, however, embodiments according to the present disclosure are not limited thereto or thereby. The electronic apparatus EA may be applied to a large-sized electronic item, such as a television set or a monitor, and a small and medium-sized electronic item, such as a mobile phone, a tablet computer, a car navigation, a game unit, or a smartwatch.

The electronic apparatus EA may display an image IM through a display surface FS, which is parallel (or substantially parallel) to each of a first direction DR1 and a second direction DR2, toward a third direction DR3. The display surface FS through which the image IM is displayed may correspond to a front surface of the electronic apparatus EA and a front surface FS of a window module WM. Hereinafter, the display surface and the front surface of the electronic apparatus EA and the front surface of the window module WM will be assigned with the same reference numeral. The image IM may include a video and a still image. FIG. 3 shows a clock widget and application icons as a representative example of the image IM.

According to some embodiments, front (or upper) and rear (or lower) surfaces of each member of the electronic apparatus EA may be defined with respect to a direction in which the image IM is displayed. The front and rear surfaces may be opposite to each other in the third direction DR3, and a normal line direction of each of the front and rear surfaces may be parallel (or substantially parallel) to the third direction DR3. A separation distance between the front and rear surfaces of particular member in the third direction DR3 may correspond to a thickness in the third direction DR3 of the display panel DP. Directions indicated by the first, second, and third directions DR1, DR2, and DR3 may be relative to each other, and thus, the directions indicated by the first, second, and third directions DR1, DR2, and DR3 may be changed to other directions.

According to some embodiments, the electronic apparatus EA may sense an external input TC applied from the outside. The external input TC may include various types of external inputs, such as a part of a user's body, light, heat, or pressure. According to some embodiments, the external input TC is shown as a hand of the user applied to the front surface. However, this is merely one example, and the external input TC may be provided in various ways. In addition, the electronic apparatus EA may sense the external input TC applied to a side or rear surface of the electronic apparatus EA depending on its structure, and it should not be limited to a specific embodiment.

Referring to FIG. 4, the electronic apparatus EA may include the window module WM, a housing unit HM, and the display module DM. According to some embodiments, the window module WM and the housing unit HM may be coupled to each other to provide an exterior of the electronic apparatus EA.

The window module WM may include an insulating panel. For example, the window module WM may include a glass material, a plastic material, or a combination thereof.

The front surface FS of the window module WM may define the front surface of the electronic apparatus EA as described above. A transmission area TA may be an optically transparent area. For example, the transmission area TA may be an area having a visible light transmittance of 90% (or about 90%) or more.

A bezel area BZA may be an area having a relatively lower transmittance as compared with the transmission area TA. The bezel area BZA may define a shape of the transmission area TA. The bezel area BZA may be adjacent to the transmission area TA and may surround the transmission area TA.

The bezel area BZA may have a selected color. The bezel area BZA may be defined by a bezel layer that is provided separately from a transparent substrate defining the transmission area TA or may be defined by an ink layer formed by being inserted into or by printing a color on the transparent substrate.

The bezel area BZA may cover a peripheral area NAA of the display module DM to prevent or reduce perceptibility or visibility of the peripheral area NAA from the outside. However, this is merely an example, and according to some embodiments, the bezel area BZA may be omitted from the window module WM.

The display module DM may include the display panel DP and an input sensor ISP located on the display panel DP. The display panel DP may generate the image IM, and the input sensor ISP may obtain coordinate information of the external input (e.g., a touch event).

The display module DM may display the image in response to electrical signals and may transmit/receive information on the external input. The display module DM may display the image IM and may sense the external input TC. A front surface IS of the display module DM may include an active area AA (or a display area) and the peripheral area NAA (or a non-display area).

According to some embodiments, the active area AA may be an area where the image IM is displayed and the external input TC is sensed. The active area AA may be an area that is activated in response to electrical signals.

The active area AA may overlap at least a portion of the transmission area TA. As an example, the transmission area TA may overlap all or at least a portion of the active area AA. Accordingly, a user may view the image IM or may provide the external input TC via the transmission area TA, however, this is merely an example. That is, an area through which the image IM is displayed and an area through which the external input TC is sensed may be separated from each other in the active area AA, and they should not be limited to a particular embodiment.

The peripheral area NAA may be covered by the bezel area BZA. The peripheral area NAA may be an area at which the image IM is not displayed. A driving circuit or a driving line to drive the active area AA may be arranged in the peripheral area NAA. The peripheral area NAA may be defined adjacent to (e.g., in a periphery or outside a footprint of) the active area AA. The peripheral area NAA may surround the active area AA. However, this is merely an example, and the peripheral area NAA may be defined in various shapes and should not be particularly limited. According to some embodiments, the peripheral area NAA of the display module DM may be omitted.

The display module DM may include the display panel DP and the input sensor ISP.

The display panel DP may include a display substrate AP and an encapsulation substrate EP. The display panel DP may be a light emitting type display panel. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel will be described as the display panel DP.

The input sensor ISP may be located directly on the display panel DP. According to some embodiments, the input sensor ISP may be formed on the display panel DP through a continuous process. That is, when the input sensor ISP is located directly on the display panel DP, an adhesive film that attaches the input sensor ISP to the display panel DP may be omitted. In addition, according to some embodiments, the input sensor ISP may be omitted from the display module DM.

The electronic apparatus may further include an anti-reflective layer located directly on the display module DM. The anti-reflective layer may be located directly on the input sensor ISP or may be located between the input sensor and the display panel DP. The anti-reflective layer may include a black matrix layer through which a plurality of openings is defined or a color filter layer.

Pads PD connected to signal lines of the display substrate AP may be arranged in the peripheral area NAA. The pads PD may have a shape integrally formed with the signal line or may be located at a different layer from the signal line and connected to an end portion of the signal line via a contact hole penetrating an insulating layer. The pads PD may not overlap the encapsulation substrate EP when viewed in a plane (e.g., in a plan view, or a direction toward a display surface).

A circuit board FCB may include a plurality of driving elements. The driving element may include a circuit part that converts input signals from the outside into signals required for a driving chip DIC or into signals necessary to drive the display module DM. According to some embodiments, the circuit board FCB may include a ground line to discharge static electricity that flows into the circuit board FCB or into the display module DM. According to some embodiments, a separate rigid circuit board may be provided, and the circuit board FCB may include only signal lines to electrically connect the circuit board FCB and the display module DM. The circuit board FCB may include various electrical components, and the circuit board FCB should not be particularly limited.

The driving chip DIC may be mounted on the circuit board FCB. The driving chip DIC may include a driving circuit, e.g., a data driving circuit, to drive a pixel of the display panel DP. FIG. 4 shows a structure in which the driving chip DIC is mounted on the circuit board FCB, however, embodiments according to the present disclosure are not limited thereto or thereby. As an example, the driving chip DIC may be mounted on the display module DM or a main circuit board. The driving chip DIC may apply a data signal and/or a gate signal to the display panel DP and may also provide a control signal.

The circuit board FCB may be coupled to the display module DM through a bonding process. The signal lines arranged in the circuit board FCB may be electrically connected to the main circuit board through the pads PD.

The circuit board FCB may be electrically connected to the display module DM through an anisotropic conductive adhesive layer. According to some embodiments, at least a portion of the circuit board FCB may be bent when being accommodated in the housing unit HM, and the bent portion may be located under the display module DM. The circuit board FCB may be bonded to a rear surface of the display panel DP. The circuit board FCB may electrically connect the display panel DP and the main circuit board. The circuit board FCB may include at least one insulating layer and at least one conductive layer. The conductive layer may include a plurality of signal lines.

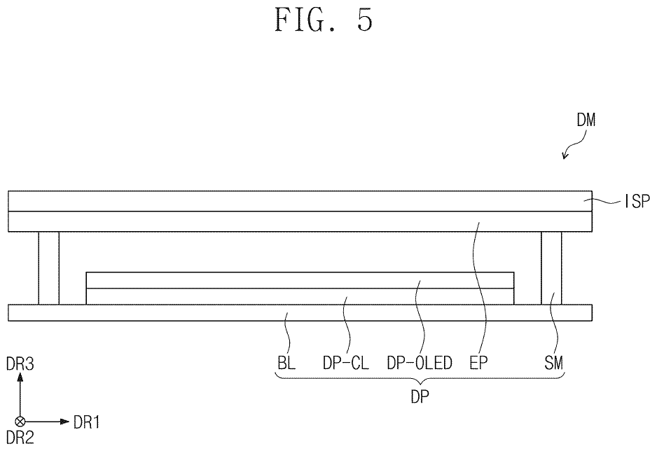

FIG. 5 is a cross-sectional view of the electronic apparatus according to some embodiments of the present disclosure.

Referring to FIG. 5, the display module DM may include the display panel DP and the input sensor ISP. According to some embodiments, the display panel DP may be a rigid type display panel.

The display panel DP may include the display substrate AP and the encapsulation substrate EP.

The display substrate AP may include a base layer BL, a circuit element layer DP-CL, and a display element layer DP-OLED. According to some embodiments, the display module DM may further include functional layers such as an anti-reflective layer.

The base layer BL may include a synthetic resin substrate or a glass substrate. The base layer BL may include a metal substrate or an organic/inorganic composite substrate.

The circuit element layer DP-CL may be located on the base layer BL. The circuit element layer DP-CL may include at least one insulating layer and a circuit element. The insulating layer may include at least one intermediate inorganic layer and at least one intermediate organic layer. The circuit element may include a signal line, a pixel driving circuit, and the like. The pixel driving circuit may include transistors and a capacitor. The circuit element layer DP-CL may be formed by forming an insulating layer, a semiconductor layer, and a conductive layer through coating and deposition processes and by patterning the insulating layer, the semiconductor layer, and the conductive layer through a photolithography process.

The display element layer DP-OLED may include a light emitting element. The light emitting element may include an organic light emitting diode or a quantum light emitting diode. The display element layer DP-OLED may further include an organic layer such as a pixel definition layer.

The encapsulation substrate EP may be located above the display element layer DP-OLED. The encapsulation substrate EP may include a synthetic resin substrate or a glass substrate. According to some embodiments, the display panel DP may be completely encapsulated from the outside by the encapsulation substrate EP. Accordingly, defects in the light emitting element, which are caused by moisture or other contaminants, may be prevented or relatively reduced.

The display panel DP may include a sealing member SM located between the display substrate AP and the encapsulation substrate EP.

The display substrate AP and the encapsulation substrate EP may be coupled to each other by the sealing member SM. The sealing member SM may include an inorganic adhesive member such as frit, however, embodiments according to the present disclosure are not limited thereto or thereby. According to some embodiments, the sealing member SM may include an organic adhesive member. The sealing member SM may block the display element layer DP-OLED from external moisture, air, etc., together with the circuit element layer DP-CL and the encapsulation substrate EP.

The input sensor ISP may be located directly on the encapsulation substrate EP. In the present disclosure, the expression “component B is located directly on component A” means that no intervening elements, such as an adhesive layer or adhesive member, are present between the component A and the component B.

The input sensor ISP may include a plurality of sensing parts to sense external inputs through a capacitive method. The input sensor ISP may be directly formed on the display panel DP when the electronic apparatus EA is manufactured. In detail, a conductive pattern or an insulating layer for the input sensor ISP may be directly deposited or patterned on the display panel DP, however, embodiments according to the present disclosure are not limited thereto or thereby. According to some embodiments, the input sensor ISP may be attached to the display panel DP by an adhesive layer after being manufactured separately from the display panel DP.

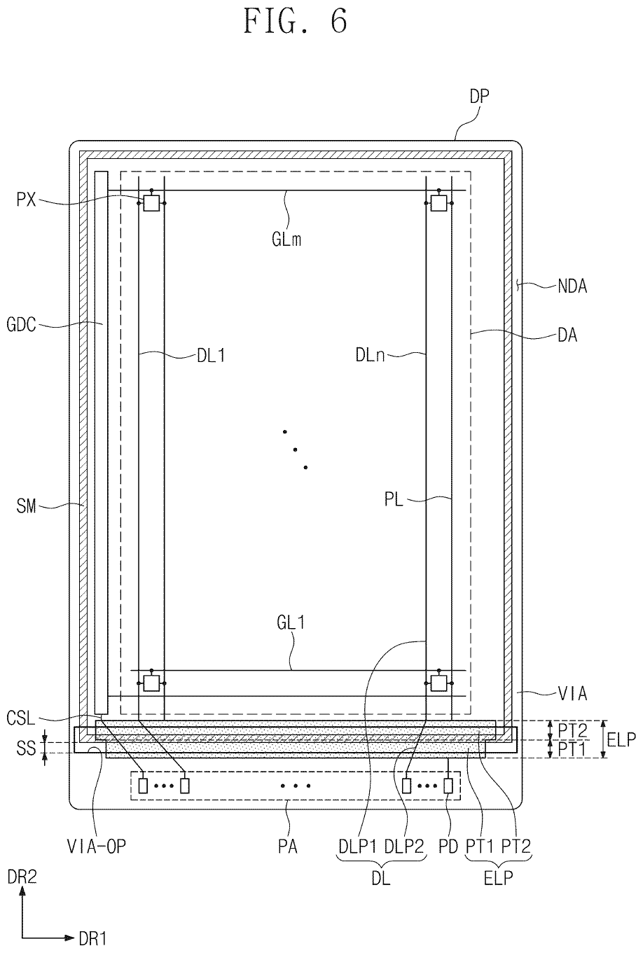

FIG. 6 is a plan view of the display panel according to some embodiments of the present disclosure. The sealing member located on the display panel is also illustrated.

Referring to FIG. 6, the display panel DP may include a display area DA and a non-display area NDA around the display area DA. The display area DA and the non-display area NDA may be distinguished from each other by a presence or absence of the pixel PX. The pixel PX may be arranged in the display area DA. A gate driving circuit GDC may be arranged in the non-display area NDA. The display area DA and the non-display area NDA of the display panel DP may correspond to the active area AA and the peripheral area NAA of the display module DM shown in FIG. 4, respectively. The display area DA and the non-display area NDA of the display panel DP do not necessarily have to be the same as the active area AA and the peripheral area NAA of the display module DM and may vary depending on the structure/design of the display panel DP.

The display panel DP may include the pixels PX, the gate driving circuit GDC, a plurality of signal lines GL1 to GLm, DL1 to DLn, PL, and CSL, and the pads PD.

The pixels PX may be arranged in the display area DA. Each of the pixels PX may include the organic light emitting diode and the pixel driving circuit connected to the organic light emitting diode. The gate driving circuit GDC and the signal lines may be included in the circuit element layer DP-CL shown in FIG. 5.

The gate driving circuit GDC may sequentially output gate signals to gate lines GL1 to GLm. The gate driving circuit GDC may include a plurality of thin film transistors formed through the same process as the pixel driving circuit of the pixels PX, e.g., a low temperature polycrystalline silicon (LTPS) process or a low temperature polycrystalline oxide (LTPO) process. The display panel DP may further include another driving circuit that applies a light emission control signal to the pixels PX.

The signal lines GL1 to GLm, DL1 to DLn, PL, and CSL may include the gate lines GL1 to GLm, data lines DL1 to DLn, a power line PL, and a control signal line CSL. The gate lines GL1 to GLm, the data lines DL1 to DLn, and the power line PL may be overlapped in the display area DA. Among the signal lines GL1 to GLm, DL1 to DLn, PL, and CSL, the control signal line CSL may overlap the non-display area NDA.

Each of the gate lines GL1 to GLm may be connected to a corresponding pixel PX among the pixels PX. Each of the data lines DL1 to DLn may be connected to a corresponding pixel PX among the pixels PX to apply the data signal. The power line PL may be connected to the pixels PX to apply power to the pixels PX. The control signal line CSL may apply control signals to the scan driving circuit.

Some of the gate lines GL1 to GLm, the data lines DL1 to DLn, the power line PL, and the control signal line CSL may be located at the same layer, and some of the gate lines GL1 to GLm, the data lines DL1 to DLn, the power line PL, and the control signal line CSL may be located at different layers.

Referring to FIG. 6, an opening VIA-OP may be defined through an organic layer VIA in the non-display area NDA. The organic layer VIA may be an organic layer covering the power line PL.

When viewed in the plane, a pad area PA may be defined adjacent to a lower end of the non-display area NDA. The pad area PA may include the pads PD. According to some embodiments, the pads PD may be arranged along the first direction DR1 and may be spaced apart from each other in the first direction DR1. At least some of the pads (PD)may be connected to an end of a power pattern ELP connected to the data lines DL1 to DLn, the control signal line CSL, and the power line PL. Another portion of the pads (PD) may be connected to touch signal lines for transmitting signals tothe input sensor ISP (refer to FIG. 5). The pads PD may be exposed an opening VIA-OP defined through the organic layer VIA.

The pad area PA may be electrically connected to the driving chip DIC and may transmit electrical signals received from the driving chip DIC to signal lines connected to the pixels PX. The circuit board FCB (refer to FIG. 4) may be electrically connected to the pads PD.

According to some embodiments, the display panel DP may include the power pattern ELP connected to the power line PL. The power pattern ELP may be located in the non-display area NDA. The power pattern ELP may include a first portion PT1 having a first width in the first direction DR1 and a second portion PT2 having a second width greater than the first width in the first direction DR1. That is, the power pattern ELP may include a side surface having a step difference in the second direction DR2.

The first portion PT1 may overlap a separation space SS described later when viewed in the plane, and the second portion PT2 may not overlap the separation space SS when viewed in the plane. The first portion PT1 may be connected to the power line PL located in the display area DA, and the second portion PT2 may be connected to the pad area PA defined adjacent to the lower end of the non-display area NDA. However, the shape of the power pattern ELP may be modified in various ways and should not be particularly limited.

Referring to FIG. 6, the sealing member SM may be located in the non-display area NDA. The sealing member SM may be arranged along a periphery of the display area DA to surround the display area DA. The sealing member SM may cover at least a portion of the power pattern ELP.

At least a portion of the sealing member SM may be spaced apart from the organic layer VIA. In detail, a portion of the sealing member SM, which overlaps the power pattern ELP when viewed in the plane, may be spaced apart from the organic layer VIA. That is, the separation space SS may be defined between the sealing member SM and the organic layer VIA. In this case, the separation space SS may be adjacent to the pad area PA.

According to some embodiments, a vertical distance (hereinafter, referred to as a width of the separation space SS) in the second direction DR2 of the separation space SS when viewed in the plane may be smaller than or equal to 58 (or about 58) micrometers. When the width of the separation space SS located in the non-display area NDA is smaller than or equal to 58 (or about 58) micrometers, a size of the bezel area BZA (refer to FIG. 4) of the window WM (refer to FIG. 4) to cover the non-display area NDA may be reduced, and thus, the electronic apparatus with relatively improved visibility may be provided.

According to some embodiments, the display panel DP may further include a bank located between the display area DA and the pad area PA. In addition, the display panel DP may further include a dam surrounding an edge of the display area DA. When a particular layer is formed by printing during fabrication of the display panel DP, the bank and the dam may prevent or reduce the particular layer overflowing beyond the bank or the dam.

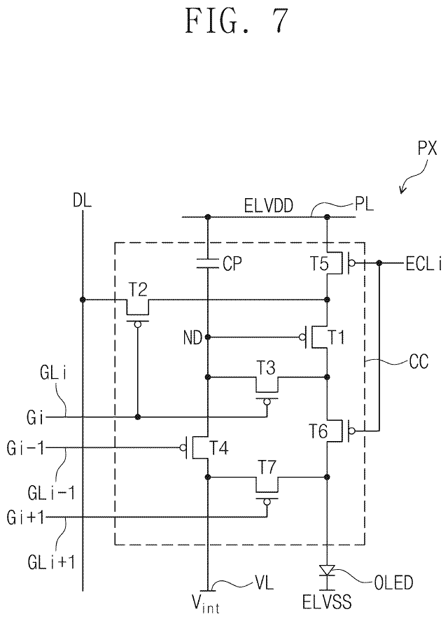

FIG. 7 is an equivalent circuit diagram of a pixel according to some embodiments of the present disclosure. Although FIG. 7 illustrates various components in a pixel according to some embodiments, embodiments according to the present disclosure are not limited thereto, and according to various embodiments, the pixel may include additional components, or fewer components, without departing from the spirit and scope of embodiments according to the present disclosure.

FIG. 7 shows the pixel PX connected to an i-th gate line GLi, an (i−1)th gate line GLi−1, an (i+1)th gate line GLi+1, and an i-th light emission control line ECLi as a representative example. In this example, the first power line (PL) may correspond to the power line (PL) of FIG. 6.

The pixel PX may include the light emitting element OLED and a pixel circuit CC. The pixel circuit may include a plurality of transistors T1 to T7 and a capacitor CP. The pixel circuit may control an amount of current flowing through the light emitting element OLED in response to the data signal.

The light emitting element OLED may emit light at a selected luminance corresponding to the amount of current provided from the pixel circuit. To this end, a voltage level of a first power supply voltage ELVDD may be set higher than a voltage level of a second power supply voltage ELVSS. The first power supply voltage ELVDD may be provided to a first power line PL.

Each of the transistors T1 to T7 may include a source, a drain, and a gate. The source, drain, and gate may be implemented either as electrodes or as portions of a semiconductor pattern. The semiconductor-type source, drain, and gate may include semiconductor regions with high doping concentrations, which are conductive (or substantially conductive). On the other hand, regions that are undoped or have low doping concentrations may serve as an active of the transistor.

In the present disclosure, for the sake of explanation, one of the source and the drain may be referred to as a first electrode, and the other of the source and the drain may be referred to as a second electrode. In addition, the gate may be referred to as a control electrode.

A first transistor T1 may include a first electrode connected to the first power line PL via a fifth transistor T5 and a second electrode connected to an anode of the light emitting element OLED via a sixth transistor T6.

The first transistor T1 may be referred to as a driving transistor. The first transistor T1 may control an amount of current flowing through the light emitting element OLED in response to a voltage applied to a control electrode thereof.

A second transistor T2 may be connected between data lines DL1 to DLn and the first electrode of the first transistor T1. The second transistor T2 may include a control electrode connected to the i-th gate line GLi. The second transistor T2 may be turned on when an i-th gate signal Gi is applied to the i-th gate line GLi to electrically connect the data line DL and the first electrode of the first transistor T1.

A third transistor T3 may be connected between the second electrode and the control electrode of the first transistor T1. The third transistor T3 may include a control electrode connected to the i-th gate line GLi. The third transistor T3 may be turned on when the i-th gate signal Gi is applied to the i-th gate line GLi to electrically connect the second electrode and the control electrode of the first transistor T1. Accordingly, when the third transistor T3 is turned on, the first transistor T1 may be connected in a diode configuration.

A fourth transistor T4 may be connected between a control node ND and a second power line VL. The fourth transistor T4 may include a control electrode connected to the (i−1)th gate line GLi−1. The fourth transistor T4 may be turned on when an (i−1)th gate signal Gi−1 is applied to the (i−1)th gate line GLi−1 to provide an initialization voltage Vint to the control node ND.

The fifth transistor T5 may be connected between the first power line PL and the first electrode of the first transistor T1. The fifth transistor T5 may include a control electrode connected to the i-th light emission control line ECLi.

The sixth transistor T6 may be connected between the second electrode of the first transistor T1 and the anode of the light emitting element OLED. The sixth transistor T6 may include a control electrode connected to the i-th light emission control line ECLi.

A seventh transistor T7 may be connected between the second power line VL and the anode of the light emitting element OLED. The seventh transistor T7 may include a control electrode connected to the (i+1)th gate line GLi+1. The seventh transistor T7 may be turned on when an (i+1)th gate signal Gi+1 is applied to the (i+1)th gate line GLi+1 to provide the initialization voltage Vint to the anode of the light emitting element OLED.

The capacitor CP may be connected between the first power line PL and the control node ND. The capacitor CP may be charged with a voltage corresponding to the data signal. When the fifth transistor T5 and the sixth transistor T6 are turned on, an amount of current flowing through the first transistor T1 may be determined depending on the voltage charged in the capacitor CP.

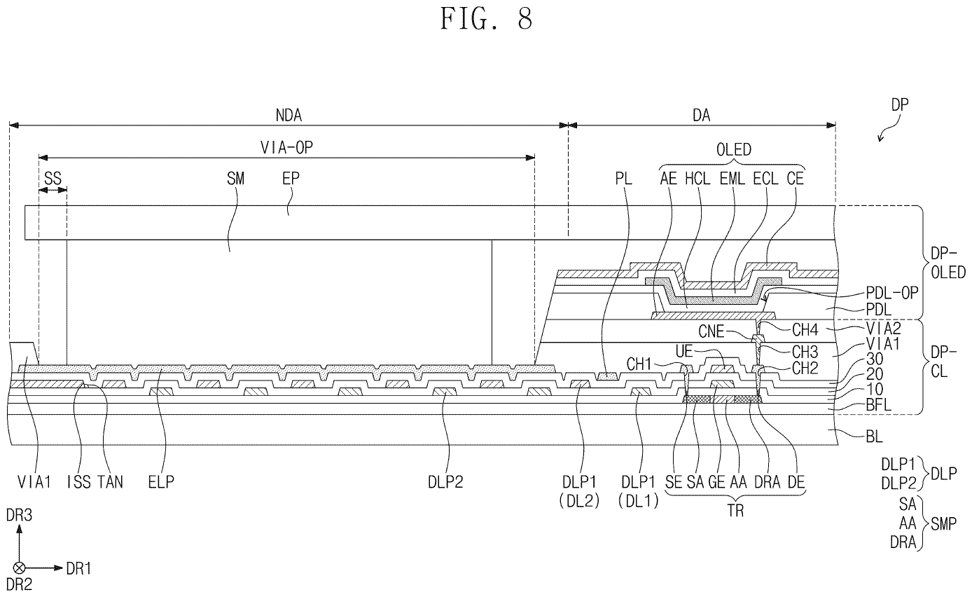

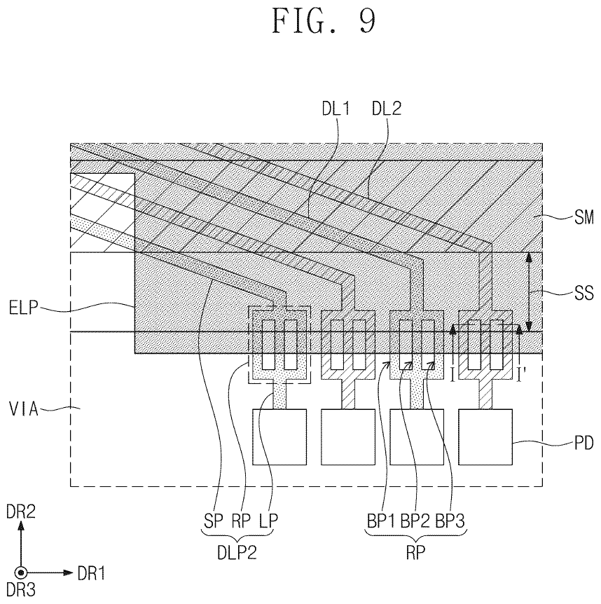

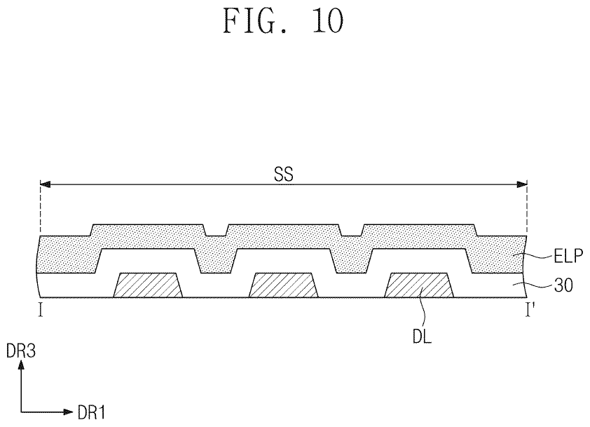

FIG. 8 is a cross-sectional view of the display panel according to some embodiments of the present disclosure. FIG. 9 is an enlarged view of a portion of the display panel adjacent to the pad area PA (refer to FIG. 6) according to some embodiments of the present disclosure. FIG. 10 is a cross-sectional view of the display panel taken along a line I-I′ of FIG. 9. Hereinafter, in FIGS. 8 to 10, the same/similar reference numerals denote the same/similar elements in FIG. 6, and thus, detailed descriptions of the same/similar elements will be omitted.

Referring to FIG. 8, the display panel DP may include the base layer BL, the circuit element layer DP-CL, the display element layer DP-OLED, and the encapsulation substrate EP.

The display panel DP may include a plurality of insulating layers, a semiconductor pattern, a conductive pattern, and a signal line. An insulating layer, a semiconductor layer, and a conductive layer may be formed by a coating or depositing process. Then, the insulating layer, the semiconductor layer, and the conductive layer may be selectively patterned by photolithography and etching processes. Thus, the semiconductor pattern, the conductive pattern, and the signal line included in the circuit element layer DP-CL and the display element layer DP-OLED may be formed.

The base layer BL may include a glass substrate, a sapphire substrate, a plastic film, or an organic/inorganic stacked-film. The base layer BL may have a single-layer or multi-layer structure. As an example, the base layer BL may include a stack structure of a plurality of plastic films attached to each other by an adhesive or a stack structure of a glass substrate and a plastic film attached to the glass substrate by an adhesive. The base layer BL may have flexibility. As an example, the base layer BL may include polyimide (PI), however, this is merely an example. According to some embodiments, the base layer BL may be a rigid substrate, but it should not be particularly limited.

Referring to FIG. 8, the circuit element layer DP-CL may be located on the base layer BL. The circuit element layer DP-CL may include a buffer layer BFL, pixel drivers, and a plurality of insulating layers 10, 20, 30, VIA1, and VIA2.

For the convenience of explanation, FIG. 8 shows one transistor TR, an upper electrode UE, and a connection electrode among the pixel drivers and shows the insulating layers 10, 20, 30, VIA1, and VIA2 that are sequentially stacked, however, this is merely an example. According to some embodiments, the configuration and arrangement of the pixel drivers constituting the circuit element layer DP-CL, as well as the number of insulating layers, may be modified in various ways and should not be particularly limited.

The buffer layer BFL may be located on the base layer BL. The buffer layer BFL may enhance an adhesion between the base layer BL and the semiconductor pattern. The buffer layer BFL may include a silicon oxide layer and a silicon nitride layer, and in this case, the silicon oxide layer and the silicon nitride layer may be alternately stacked with each other.

The semiconductor pattern SMP may be located on the buffer layer BFL. The semiconductor pattern SMP may include silicon semiconductor. The semiconductor pattern SMP may include polycrystalline silicon semiconductor, however, embodiments according to the present disclosure are not limited thereto or thereby. According to some embodiments, the semiconductor pattern SMP may include amorphous silicon. FIG. 8 shows one semiconductor pattern SMP among semiconductor patterns as a representative example, and one or more semiconductor patterns may further be arranged in a plurality of light emitting areas. The semiconductor pattern SMP may include a plurality of regions distinguished from each other by their electrical conductivity.

The semiconductor pattern SMP may include a source area SA, an active area AA, and a drain area DRA. The active area AA may have a relatively low electrical conductivity compared to the source area SA and the drain area DRA. The source area SA and the drain area DRA may be spaced apart from each other, and the active area AA may be located between the source area SA and the drain area DRA. The active area AA of the semiconductor pattern SMP may be defined to correspond to a gate electrode GE described later.

A first insulating layer 10 may be located on the buffer layer BFL. The first insulating layer 10 may commonly overlap the pixels PX and may cover the semiconductor pattern SMP. The first insulating layer 10 may be an inorganic layer and/or an organic layer and may have a single-layer or multi-layer structure. The first insulating layer 10 may include at least one of aluminum oxide, titanium oxide, silicon oxide, silicon oxynitride, zirconium oxide, or hafnium oxide.

The gate electrode GE may be located on the first insulating layer 10. According to some embodiments, the transistor TR may have a top-gate structure, however, this is merely an example. According to some embodiments, the gate electrode GE may be located under the semiconductor pattern SMP and should not be particularly limited.

A second insulating layer 20 (or a first inorganic layer) may be located on the first insulating layer 10 to cover the gate electrode GE. The second insulating layer 20 may commonly overlap the pixels PX. The second insulating layer 20 may be an inorganic layer and may have a single-layer or multi-layer structure. The second insulating layer 20 may include at least one of aluminum oxide, titanium oxide, silicon oxide, silicon oxynitride, zirconium oxide, or hafnium oxide.

The upper electrode UE may be located on the second insulating layer 20. The upper electrode UE may be a part of a metal pattern. A portion of the gate electrode GE and the upper electrode UE overlapping the portion of the gate electrode GE may define a capacitor.

A third insulating layer 30 (or a second inorganic layer) may be located on the second insulating layer 20 to cover the upper electrode UE. The third insulating layer 30 may be an inorganic layer and may have a single-layer or multi-layer structure. The third insulating layer 30 may include at least one of aluminum oxide, titanium oxide, silicon oxide, silicon oxynitride, zirconium oxide, or hafnium oxide.

A source electrode SE and a drain electrode DE may be located on the third insulating layer 30. The source electrode SE and the drain electrode DE may be connected to the semiconductor pattern SMP via a first contact hole CH1 and a second contact hole CH2, which respectively expose the source area SA and the drain area DRA of the semiconductor pattern SMP. In this case, the first contact hole CH1 and the second contact hole CH2 may penetrate through the first, second, and third insulating layers 10, 20, and 30.

A first organic layer VIA1 may be located on the third insulating layer 30 to cover the source electrode SE and the drain electrode DE. The first organic layer VIA1 may correspond to the organic layer VIA of FIG. 6. The first organic layer VIA1 may have a single-layer or multi-layer structure.

The connection electrode CNE may be located on the first organic layer VIA1. The connection electrode CNE may be connected to the drain electrode DE via a third contact hole CH3 defined through the first organic layer VIA1.

A second organic layer VIA2 may be located on the first organic layer VIA1 to cover the connection electrode CNE. The second organic layer VIA2 may have a single-layer or multi-layer structure.

According to some embodiments, the first organic layer VIA1 and the second organic layer VIA2 may be a polyimide-based resin layer having a single-layer structure, however, embodiments according to the present disclosure are not limited thereto or thereby. According to some embodiments, the first organic layer VIA1 and the second organic layer VIA2 may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin.

The light emitting element OLED may be located on the second organic layer VIA2. The anode AE of the light emitting element OLED may be located on the second organic layer VIA2. The anode AE may be connected to the connection electrode CNE via a fourth contact hole CH4 defined through the second organic layer VIA2.

The display element layer DP-OLED may include the light emitting element OLED and the pixel definition layer PDL. The pixel definition layer PDL may be located on the second organic layer VIA2. At least one light emitting opening PDL-OP may be defined through the pixel definition layer PDL. At least a portion of the anode AE may be exposed through the light emitting opening PDL-OP of the pixel definition layer PDL. The light emitting opening PDL-OP of the pixel definition layer PDL may define the light emitting area of the pixel PX. For instance, the pixels PX may be arranged in a specific rule on the display panel DP when viewed in the plane. An area where the pixels PX are arranged may correspond to the display area DA described with reference to FIG. 6, and the display area DA may include the light emitting areas and a non-light-emitting area adjacent to the light emitting areas. The non-light-emitting area may surround the light emitting areas when viewed in the plane.

A hole control layer HCL may be located on the anode AE. The hole control layer HCL may be commonly located in the light emitting areas and the non-light-emitting area. A common layer like the hole control layer HCL may be commonly formed in the pixels PX. The hole control layer HCL may include a hole transport layer and a hole injection layer.

A light emitting layer EML may be located on the hole control layer HCL. The light emitting layer EML may be located in an area corresponding to the light emitting opening PDL-OP. The light emitting layer EML may be formed separately for each of the pixels PX.

According to some embodiments, the patterned light emitting layer EML is shown as a representative example, however, the light emitting layer EML may be commonly arranged across the pixels PX. In this case, the light emitting layer EML may emit a white light. In addition, the light emitting layer EML may have a multi-layer structure, but it should not be particularly limited.

An electron control layer ECL may be located on the light emitting layer EML. The electron control layer ECL may include an electron transport layer and an electron injection layer.

A cathode CE may be located on the electron control layer ECL. The electron control layer ECL and the cathode CE may be commonly arranged across the pixels PX.

The encapsulation substrate EP may be located on the cathode CE. The encapsulation substrate EP may encapsulate the display element layer DP-OLED. The encapsulation substrate EP may protect the pixels from external contaminants such as moisture, oxygen, or other foreign substances. According to some embodiments, the encapsulation substrate EP may not overlap at least a portion of the base layer BL, however, embodiments according to the present disclosure are not limited thereto or thereby. As an example, the encapsulation substrate EP may overlap the entire area of the base layer BL and should not be particularly limited.

The sealing member SM may be located in the non-display area NDA. The sealing member SM may be located on the power pattern ELP. The sealing member SM may be located between the encapsulation substrate EP and the power pattern ELP to couple the encapsulation substrate EP to the circuit element layer DP-CL. At least a portion of the sealing member SM may be spaced apart from the organic layer VIA.

According to some embodiments, the data line DL may include a first line DL1 located under the second insulating layer 20 and a second line DL2 located between the second insulating layer 20 and the third insulating layer 30. The first line DL1 may be located at the same layer as the gate electrode GE and may include the same material as the gate electrode GE. The second line DL2 may be located at the same layer as a gate electrode of a transistor different from the transistor TR shown in FIG. 8 and may include the same material as the gate electrode of the transistor.

The data line DL may include a first data line part DLP1 located in the display area DA and a second data line part DLP2 located in the non-display area NDA. The second data line part DLP2 may be electrically connected to the first data line part DLP1. The second data line part DLP2 may be located at the same layer as a part of the first data line part DLP1. That is, the first data line part DLP1 may include the first line DL1 located under the second insulating layer 20 and the second line DL2 located between the second insulating layer 20 and the third insulating layer 30.

Referring to FIG. 8, the power line PL may be located on the data line DL. The power line PL may be located at the same layer as the source electrode SE and the drain electrode DE and may include the same material as the source electrode SE and the drain electrode DE.

According to some embodiments, the display panel DP may include the power pattern ELP connected to the power line PL. The power pattern ELP may be located in the non-display area NDA. The power pattern ELP may be located on the third insulating layer 30. The power pattern ELP may be located at the same layer as the power line PL. The power pattern ELP may be located at the same layer as the source electrode SE and drain electrode DE and may include the same material as the source electrode SE and the drain electrode DE. The power pattern ELP may overlap the second data line part DLP2 when viewed in the plane.

Referring to FIG. 9, the second data line part DLP2 located in the non-display area NDA may include a slant portion SP slanted with respect to the first direction DR1 when viewed in the plane and a linear portion LP extending from the slant portion SP along the second direction DR2. The linear portion LP may be connected to pads PD. The pads PD shown in FIG. 9 may correspond to the pads PD shown in FIG. 6. According to some embodiments, the sealing member SM may overlap at least a portion of the slant portion SP, and the organic layer VIA may overlap at least a portion of the linear portion LP.

The second data line part DLP2 may further include a branch portion RP branched from the linear portion LP. The branch portion RP may include a plurality of branches BP1, BP2, and BP3 extending in the second direction DR2. When the circuit board FCB (refer to FIG. 4) is bent toward the rear surface of the display panel DP, a tensile stress may be applied to the second data line part DLP2, which may cause cracks or short circuits in the lines. As described above, because the branch portion RP of the second data line part DLP2 includes the branches BP1, BP2, and BP3 spaced apart from each other, the tensile stress may be distributed in the branches BP1, BP2, and BP3, and thus, defects such as cracks or short circuits may be reduced or prevented. The number of the branches of the branch portion RP should not be particularly limited.

The sealing member SM may be spaced apart from the first organic layer VIA1 in the non-display area NDA. That is, the separation space SS may be defined between the sealing member SM and the first organic layer VIA1.

According to some embodiments, at least a portion of the separation space SS between the first organic layer VIA1 and the sealing member SM may overlap the power pattern ELP when viewed in the plane. The power pattern ELP may cover the inorganic layer 30 (or the third insulating layer) overlapping the separation space SS. Because the inorganic layer 30 is covered by the power pattern ELP without being exposed in the separation space SS, cracks in the second data line part DLP2, which are caused by external force, may be reduced compared to a structure in which the inorganic layer 30 is exposed to the outside.

In addition, according to some embodiments, at least a portion of the branch portion RP may overlap the separation space SS when viewed in the plane. The branch portion RP of the second data line part DLP2 located in the separation space SS may be covered by the power pattern ELP. As described above, an interval between the lines arranged in the branch portion RP may be smaller than an interval between the lines arranged in other areas. That is, the interval between the lines of the branch portion RP may be reduced, and the risk of line defects such as cracks or short circuits may increase.

According to the present disclosure, spaces between the branches BP1, BP2, and BP3 of the branch portion RP, which are arranged at fine intervals, may be covered by the power pattern ELP. Because the spaces between branches BP1, BP2, and BP3 are covered by the power pattern ELP in the separation space SS without being exposed, the occurrence of defects in the lines arranged in the branch portion RP may be reduced compared to the structure in which the branch portion RP is exposed to the outside.

As described above, the width of the separation space SS may be smaller than or equal to 58 micrometers (or about 58 micrometers). When the width of the separation space SS defined in the non-display area NDA is smaller than or equal to 58 (or about 58) micrometers, an angle TAN (hereinafter, referred to as a tapered angle) between a slant surface ISS (refer to FIG. 8) of the data line DL located in the separation space SS and an upper surface of the inorganic layer 20 (or the second insulating layer) located under the data line DL may increase. When the tapered angle TAN of the data line DL increases, the inorganic layer 30 (or the third insulating layer) formed on upper and side surfaces of the data line DL may become thinner or may not be uniformly coated. Fine cracks may occur in the inorganic layer 30, and moisture or chemicals may infiltrate into the data line DL through the cracks. Accordingly, as molybdenum is eluted from the data line DL, the data line DL may become disconnected or may short-circuit with adjacent signal lines.

Referring to FIG. 10, the inorganic layer 30 may cover the data line DL located in the separation space SS. In this case, an upper surface of the inorganic layer 30 may be entirely covered by the power pattern ELP. That is, the upper surface of the inorganic layer 30 may be in direct contact with the power pattern ELP. In this case, even though cracks occur in the inorganic layer 30 covering the data line DL due to the increase of the tapered angle TAN (refer to FIG. 8), portions where cracks occur may be covered by the power pattern ELP, and thus, the degree to which moisture or chemicals infiltrates into the data line DL through the cracks may be reduced. Consequently, the elution of molybdenum from the data line DL may be prevented or relatively reduced, the disconnection and short-circuit may be reduced, and thus, electrical characteristics of the electronic apparatus may be relatively improved.

Although aspects of some embodiments of the present disclosure have been described, it is understood that embodiments according to the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the appended claims, and their equivalents.

What is claimed is:

1. An electronic apparatus comprising:
a base layer comprising a display area and a non-display area;
a pixel in the display area;
a power line configured to provide a power to the pixel;
a data line configured to provide a data signal to the pixel and comprising a first data line part in the display area and a second data line part connected to the first data line part and in the non-display area;
an inorganic layer covering the data line;
a power pattern connected to the power line, on the inorganic layer, and overlapping the second data line part;
a sealing member in the non-display area along a periphery of the display area and covering at least a portion of the power pattern;
an encapsulation substrate on the sealing member; and
an organic layer on the inorganic layer, wherein at least a portion of the organic layer is spaced apart from the sealing member in a plan view, and a portion of the inorganic layer, which overlaps a separation space between the organic layer and the sealing member, is covered by the power pattern.

2. The electronic apparatus of claim 1, wherein the pixel comprises:
a transistor comprising a gate electrode, a source electrode, a drain electrode, and a semiconductor pattern; and
a light emitting element comprising an anode, a cathode, and a light emitting layer, and the data line is at a same layer as the gate electrode.

3. The electronic apparatus of claim 2, wherein the source electrode or the drain electrode is at a same layer as the power pattern.

4. The electronic apparatus of claim 2, wherein the organic layer is at a same layer as an insulating layer between the anode and the source electrode.

5. The electronic apparatus of claim 1, wherein the first data line part and the second data line part are at a same layer.

6. The electronic apparatus of claim 5, wherein the power line is on the first data line part, and the power pattern is on the second data line part.

7. The electronic apparatus of claim 1, wherein the inorganic layer comprises a first inorganic layer and a second inorganic layer on the first inorganic layer, and the data line comprises a first line under the first inorganic layer and a second line between the first inorganic layer and the second inorganic layer.

8. The electronic apparatus of claim 1, wherein the power pattern comprises:
a first portion that overlaps the separation space in the plan view and has a first width in a direction; and
a second portion that does not overlap the separation space in the plan view and has a second width greater than the first width in the direction.

9. The electronic apparatus of claim 8, wherein a vertical distance of the separation space in the direction is smaller than or equal to 58 micrometers in the plan view.

10. The electronic apparatus of claim 1, wherein the second data line part comprises:
a slant portion slanted with respect to a direction in the plan view; and
a linear portion extending from the slant portion along the direction, and the sealing member overlaps at least a portion of the slant portion, and the organic layer overlaps at least a portion of the linear portion.

11. The electronic apparatus of claim 10, wherein the second data line part further comprises a branch portion branched from the linear portion and comprising a plurality of branches extending in the direction, and at least a portion of the branch portion overlaps the separation space in the plan view.

12. The electronic apparatus of claim 1, further comprising a pad part connected to the data line, wherein the pad part is exposed without being covered by the organic layer.

13. An electronic apparatus comprising:
a base layer comprising a display area and a non-display area;
a pixel in the display area;
a power line configured to provide a power to the pixel;
a gate line extending in a first direction;
a data line comprising a first data line part extending in a second direction intersecting the first direction and in the display area and a second data line part connected to the first data line part and in the non-display area;
an inorganic layer covering the data line;
a power pattern connected to the power line, on the inorganic layer, and overlapping the second data line part;
a sealing member in the non-display area along a periphery of the display area and covering at least a portion of the power pattern;
an encapsulation substrate on the sealing member; and
an organic layer on the inorganic layer and spaced apart from the sealing member in the second direction in a plan view, wherein at least a portion of a separation space between the organic layer and the sealing member overlaps the power pattern in the plan view.

14. The electronic apparatus of claim 13, wherein the pixel comprises:
a transistor comprising a gate electrode, a source electrode, a drain electrode, and a semiconductor pattern; and
a light emitting element comprising an anode, a cathode, and a light emitting layer, and the data line is at a same layer as the gate electrode.

15. The electronic apparatus of claim 14, wherein the source electrode or the drain electrode is at a same layer as the power pattern.

16. The electronic apparatus of claim 13, wherein the first data line part and the second data line part are at a same layer.

17. The electronic apparatus of claim 13, wherein the second data line part comprises:
a slant portion slanted with respect to the first and second directions in the plan view; and
a linear portion extending from the slant portion along the second direction, the sealing member overlaps at least a portion of the slant portion, and the organic layer overlaps at least a portion of the linear portion.

18. The electronic apparatus of claim 17, wherein the second data line part further comprises a branch portion branched from the linear portion and comprising a plurality of branches extending in the second direction, and at least a portion of the branch portion overlaps the separation space in the plan view.

19. The electronic apparatus of claim 13, wherein at least a portion of the organic layer overlaps the power pattern in the plan view.

20. The electronic apparatus of claim 13, wherein a width of the separation space in the second direction is smaller than or equal to 58 micrometers in the plan view.
